(19) United States
(12) Patent Application Publication
(10) Pub. No.: US 2009/0134380 A1
(43) Pub. Date: May 28, 2009

(54) SOLID-STATE LIGHTING ELEMENT

(75) Inventor: GA-LANE CHEN, Santa Clara, CA (US)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/192,039

(22) Filed: Aug. 14, 2008

(30) Foreign Application Priority Data
Nov. 26, 2007 (CN) 200710202668.4

(51) Int. Cl. H01L 33/00; H01L 21/02

(52) U.S. Cl. 257/13; 257/99; 257/103; 438/26; 257/E21.002; 257/E33.062; 257/E33.013

(57) ABSTRACT

A solid-state lighting element includes a transparent electrically conductive substrate, a first type confinement layer disposed on the transparent electrically conductive substrate, an active layer disposed on the first type confinement layer, a second type confinement layer disposed on the active layer, an electrode contacting and disposed on the second type confinement layer. The transparent electrically conductive substrate is made of Hydrogenated Silicon Carbides. A heat generated by the LED can be efficiently dissipated through the transparent electrically conductive substrate in time as the SiC:H is a material of high conductivity and high thermo-conductivity. Therefore, a quantum efficiency of the LED 10 is improved and preserved.

### BACKGROUND

1. Technical Field

The present invention relates to a solid-state lighting element, and particularly, to a solid-state lighting element having good heat dissipation efficiency and a method of making same.

2. Description of related art

Semiconductor light emitting diodes (LEDs), as a solid-state lighting element, are semiconductor chips being used to emit light in response to an applied voltage or current. The LEDs typically include a substrate, a luminescence configuration disposed on the substrate, and a positive and negative electrode. The luminescence configuration includes an N-type confinement layer, a P-type confinement layer and a non-dopant active layer interposed between the N-type and P-type confinement layer. The positive electrode contacts the P-type confinement layer. The negative electrode contacts the N-type confinement layer. The LEDs can emit light that has a certain wavelength, such as ultraviolet, blue, green or red. However, the LEDs' efficiency in electro-optic conversion is low and a majority of electrical power applied thereto (about 80%-90%) is invalidly converted into heat, which increase the temperature thereof. When the temperature of the LEDs reach 70° C. or greater than 70° C., a quantum efficiency of the LEDs suffers, which further deteriorate the electro-optic conversion efficiency of the LEDs.

Therefore, what is needed is a new solid-state lighting element having good heat dissipation efficiency and a method of making same, which can overcome the above-described deficiency.

### SUMMARY

In accordance with the present invention, a solid-state lighting element includes a transparent electrically conductive substrate, a first type confinement layer disposed on the transparent electrically conductive substrate, a lighting active layer disposed on the first type confinement layer, a second type confinement layer disposed on the lighting active layer, an electrode contacting and disposed on the second type confinement layer. The transparent electrically conductive substrate is made of hydrogenated silicon carbides.

Other novel features and advantages will become more apparent from the following detailed description when taken in conjunction with the accompanying drawings.

### BRIEF DESCRIPTION OF THE DRAWINGS

The present invention is described in detail hereinafter, by way of example and description of preferred and exemplary embodiments thereof with reference to the accompanying drawings, in which:

FIG. 1 is a cross-section view of a light emitting diode according to an exemplary embodiment of the present invention; and

FIG. 2 is a flow chart of a method for forming the light emitting diode of FIG. 1.

### DETAILED DESCRIPTION OF THE EXEMPLARY EMBODIMENTS

A detailed explanation of a solid-state lighting element according to an exemplary embodiment of the present invention will now be made with reference to the drawings attached hereto.

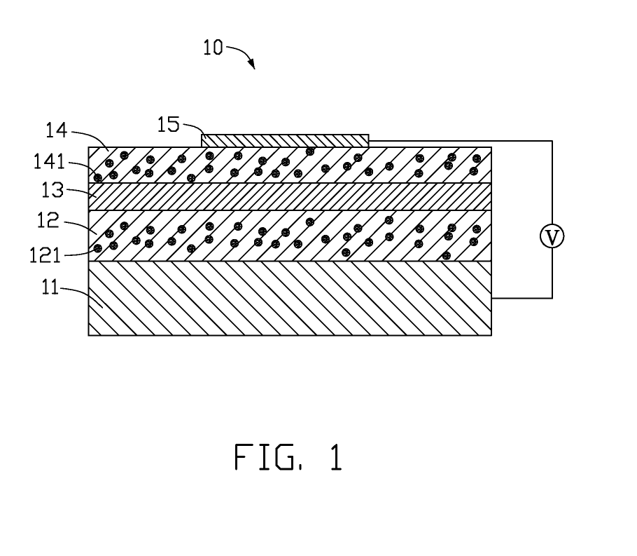

Referring to FIG. 1, a solid-state lighting element according to the exemplary embodiment is shown. It should be noted that a light emitting diode (LED) 10, as the solid-state lighting element, is presented only as example to explain the configuration and working principle of the solid-state lighting element in the exemplary embodiment. The LED 10 includes a transparent electrically conductive substrate 11, a first type confinement layer 12, a lighting active layer 13, a second type confinement layer 14, and an electrode 15 which contacts the second type confinement layer 14. The first type confinement layer 12, the lighting active layer 13, and the second type confinement layer 14 together define a luminescence configuration.

The transparent electrically conductive substrate 11 is comprised of a hydrogenated silicon carbides (SiC:H). Lights generated by the luminescence configuration can directly pass through the transparent electrically conductive substrate 11 and are emitted out of the transparent electrically conductive substrate 11 since the transparent electrically conductive substrate 11 is transparent. Understandably, the transparent electrically conductive substrate 11 can be employed as an electrode and can be connected to a power to supply voltage or current for the luminescence configuration in cooperation with the electrode 15.

The first type confinement layer 12 may be an N-type semiconductor layer containing a plurality of nano particles 121. The N-type semiconductor layer may be comprised of one of N-type GaN, N-type InP, N-type GaInP or N-type AlGaInP. In the present embodiment, the first type confinement layer 12 is an N-type GaN layer doped with silicon dopant(s). The nano particle 121 may be made of one of silicon oxide, silicon nitride, aluminum oxide, gallium oxide, boron nitride. In the present embodiment, the nano particle 121 is made of silicon oxide and has a size of 20 to 200 nm.

The lighting active layer 13 may be comprised of one of GaInN or AlGaAs and can be one of a single quantum well layer or a multilayer quantum well films. In the illustrated embodiment, the lighting active layer 13 is a single quantum well layer mage of GaInN.

The second type confinement layer 14 may be a P-type semiconductor layer containing a plurality of nano particles 141 as same as the nano particle 121. The P-type semiconductor layer may be made of one of P-type AlGaN or P-type AlGaAs. In the present embodiment, the P-type confinement layer 12 is a P-type AlGaN layer doped with magnesium or hydrogen dopant(s).

It should be noted that a density of nano particles 121, 141 in the N-type and P-type confinement layers 12, 14 can be adjusted according to a predetermined standard.

The electrode 15 may be made of Ni, Au, Ni/Au, Ti, Al, Ti/Al, Cu, Ag, Al/Cu, or Ag/Cu. In the present embodiment, the electrode 15 is made of Ag.

It should be further described that the dislocation motion between the lighting active layer 13 and the N-type and P-type confinement layers 12, 14 is decreased as the N-type and P-type confinement layers 12, 14 contain the nano particles 121, 141. The quantum efficient of the luminescence configuration in producing light can also be improved. Furthermore, the nano particles 121, 141 in the N-type and P-type confinement layers 12, 14 can change the lattice constant of the N-type and P-type semiconductor layers thereof and decrease the lattice strain thereof. As a result, the decrease of the lattice strain weakens the stress generated between the lighting active layer 13 and the N-type and P-type confinement layers 12, 14 and the quantum efficient in producing light is further improved.

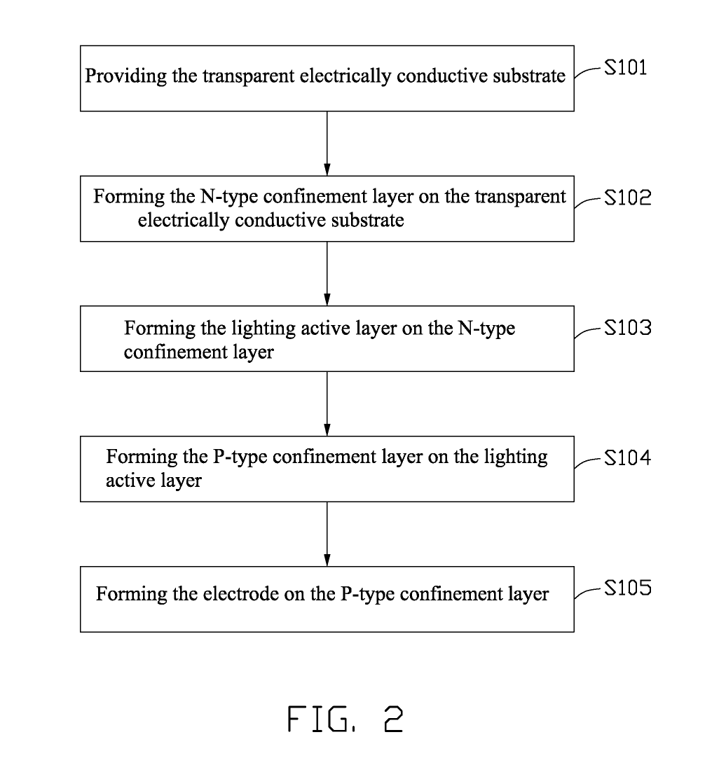

Referring to FIG. 2, a flow chart of an exemplary method for forming the LED 10 is shown. The method includes:
Step S101: providing the transparent electrically conductive substrate 11;
Step S102: forming the N-type confinement layer 12 on the transparent electrically conductive substrate 11;
Step S103: forming the lighting active layer 13 on the N-type confinement layer 12;
Step S104: forming the P-type confinement layer 14 on the lighting active layer 13; and
Step S105: forming the electrode 15 on the P-type confinement layer 14.

In step S102 through step S104, the N-type confinement layer 12, the lighting active layer 13, and the P-type confinement layer 14 are deposited on the transparent electrically conductive substrate 11 by any deposition methods such as, metal organic chemical vapor deposition (MOCVD) or plasma enhanced chemical vapor deposition (PECVD). In step S105, the electrode 15 is deposited on the P-type confinement layer 14 by a magnetron sputtering method. In the present embodiment, a gold layer (not shown) is deposited on the P-type confinement layer 14.

As described above, a heat generated by the LED 10 can be efficiently dissipated through the transparent electrically conductive substrate 11 in time as the transparent electrically conductive substrate 11 is comprised of SiC:H that has a high conductivity and high thermo-conductivity. Therefore, a quantum efficiency of the LED 10 is improved and preserved.

It should be understood that the above-described embodiment is intended to illustrate rather than limit the invention. Variations may be made to the embodiments without departing from the spirit of the invention. Accordingly, it is appropriate that the appended claims be construed broadly and in a manner consistent with the scope of the invention.

What is claimed is:

1. A solid-state lighting element, comprising:
a transparent electrically conductive substrate comprised of hydrogenated silicon carbides;
a first type confinement layer disposed on the transparent electrically conductive substrate;
a lighting active layer disposed on the first type confinement layer;
a second type confinement layer disposed on the active layer; and
an electrode contacting and disposed on the second type confinement layer.

2. The solid-state lighting element as claimed in claim 1, wherein the first type confinement layer is an N-type confinement layer comprising an N-type semiconductor layer containing a plurality of nano particles.

3. The solid-state lighting element as claimed in claim 2, wherein the nano particle is comprised of silicon oxide.

4. The solid-state lighting element as claimed in claim 2, wherein the nano particle is comprised of silicon nitride.

5. The solid-state lighting element as claimed in claim 2, wherein the nano particle is comprised of aluminum oxide.

6. The solid-state lighting element as claimed in claim 2, wherein the nano particle is comprised of gallium oxide.

7. The solid-state lighting element as claimed in claim 2, wherein the nano particle is comprised of boron nitride.

8. The solid-state lighting element as claimed in claim 2, wherein the nano particle has a size of 20 to 200 nm.

9. The solid-state lighting element as claimed in claim 2, wherein the N-type semiconductor layer is one of N-type GaN, N-type InP, N-type GaInP, and N-type AlGaInP.

10. The solid-state lighting element as claimed in claim 1, wherein the second type confinement layer is a P-type confinement layer comprising a P-type semiconductor layer containing a plurality of nano particles.

11. The solid-state lighting element as claimed in claim 10, wherein the P-type semiconductor layer is one of P-type AlGaN and P-type AlInGaP.

12. The solid-state lighting element as claimed in claim 1, wherein the lighting active layer is one of a single quantum well layer and a multilayer quantum well films.

13. A method of making a solid-state lighting element, comprising:
forming a transparent electrically conductive substrate made of Hydrogenated Silicon Carbides;
forming a first type confinement layer on the transparent electrically conductive substrate;
forming a lighting active layer on the first type confinement layer;
forming a second type confinement layer on the active layer; and
forming an electrode on the second type confinement layer.

14. The method as claimed in claim 13, wherein the step of forming the electrode comprises forming a gold layer over the second type confinement layer.
